(19) United States
(12) Patent Application Publication
(10) Pub. No.: US 2012/0025202 A1
(43) Pub. Date: Feb. 2, 2012

(54) SEMICONDUCTOR DEVICE AND METHOD FOR FABRICATING THE SAME

(75) Inventors: Isao Makabe, Kanagawa (JP); Keiichi Yui, Kanagawa (JP); Ken Nakata, Kanagawa (JP)

(73) Assignee: SUMITOMO ELECTRIC INDUSTRIES, LTD., Osaka (JP)

(21) Appl. No.: 13/194,217

(22) Filed: Jul. 29, 2011

(30) Foreign Application Priority Data
Jul. 30, 2010 (JP) 2010-171914

(51) Int. Cl. H01L 29/778; H01L 21/20

(52) U.S. Cl. 257/76; 438/478; 257/E29.246; 257/E21.09

(57) ABSTRACT

A semiconductor device includes a silicon substrate; a buffer layer provided on the silicon substrate and has a band gap greater than GaN; a first GaN layer provided on the buffer layer; and a second GaN layer provided directly on the first GaN layer, a carbon concentration of the first GaN layer being higher than a carbon concentration of the second GaN layer.

### CROSS-REFERENCE TO RELATED APPLICATION

This application is based upon and claims the benefit of priority of the prior Japanese Patent Application No. 2010-171914 filed on Jul. 30, 2010, the entire contents of which are incorporated herein by reference.

### BACKGROUND

(i) Technical Field

A certain aspect of the embodiments discussed herein is related to a semiconductor device and a method for fabricating the same. Another aspect of the embodiments is related to a semiconductor device having a GaN layer that is formed on a silicon substrate so that a buffer layer is interposed therebetween.

(ii) Related Art

A semiconductor devices using a nitride semiconductor is used as a power device operating at high frequencies and outputting high power. Particularly, there is known an FET such as a high electron mobility transistor (HEMT) as a semiconductor device suitable for amplification in a high-frequency or RF (radio Frequency) band such as a microwave band, a quasi-millimeter band or a millimeter band.

As a base material, a GaN substrate having a large size and a high quality is not available for the semiconductor devices using a nitride semiconductor. Thus, hetero-epitaxial growth on a heterologous substrate is used. For example, Japanese Patent Application Publication No. 2008-166349 discloses a semiconductor deice using a silicon device on which a GaN layer and an AlGaN electron supply layer are stacked in this order so that a buffer layer composed of an AlN layer and an AlGaN layer is interposed between the silicon substrate and the GaN layer.

There is room left for improvement in the quality of the GaN layer formed on the buffer layer on the silicon substrate.

### SUMMARY

According to an aspect of the present invention, there is provided a semiconductor device including: a silicon substrate; a buffer layer provided on the silicon substrate and has a band gap greater than GaN; a first GaN layer provided on the buffer layer; and a second GaN layer provided directly on the first GaN layer, a carbon concentration of the first GaN layer being higher than a carbon concentration of the second GaN layer.

### BRIEF DESCRIPTION OF THE DRAWINGS

FIG. 1 is a schematic cross-sectional view of a semiconductor device in accordance with a first embodiment;

FIGS. 2A through 2C are schematic cross-sectional views that illustrate a method for fabricating the semiconductor device in accordance with the first embodiment;

FIGS. 3A and 3B are schematic cross-sectional views that illustrate steps of the method subsequent to those of FIGS. 2A through 2C;

FIGS. 4A through 4C are schematic cross-sectional views that illustrate a semiconductor device in accordance with a first comparative example;

FIG. 5 illustrates the result of measurement of emission spectrum about a GaN layer of the first embodiment; and

FIG. 6 illustrates the result of measurement of emission spectrum about a GaN layer of the first comparative example.

### DETAILED DESCRIPTION

Embodiments of the invention are now described with reference to the accompanying drawings.

### First Embodiment

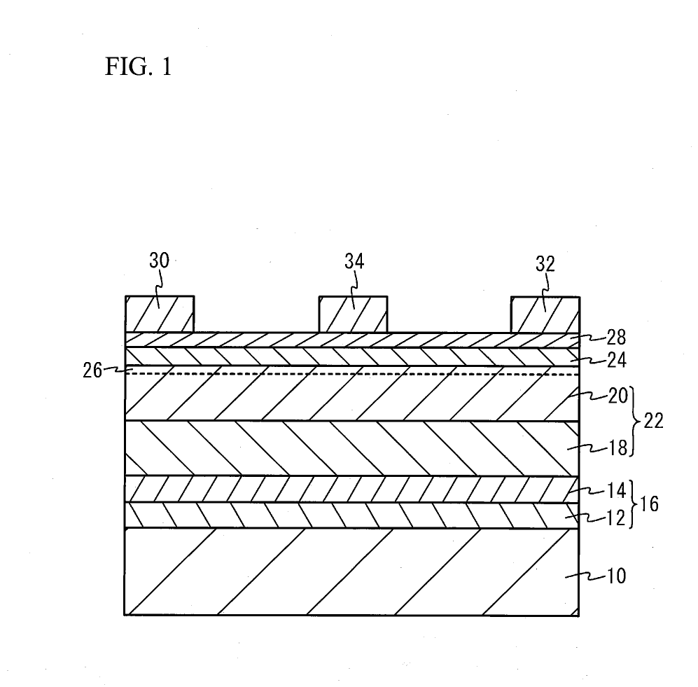

FIG. 1 is a schematic cross-sectional view of a semiconductor deice in accordance with a first embodiment. The first embodiment is an HEMT, which is an exemplary nitride semiconductor. The nitride semiconductor is a semiconductor including nitrogen, and is GaN, InN, AlN, AlGaN, InGaN, AlInGaN, or the like.

Referring to FIG. 1, a buffer layer 16 is formed directly on an upper surface of a silicon substrate 10. The buffer layer 16 is composed of an AlN layer 12 on the silicon substrate 10 and an AlGaN layer 16 formed on the AlN layer 12. The upper surface of the buffer layer 16 has no roughness and has a flat plane. A GaN layer 22 composed of a first GaN layer 18 and a second GaN layer 20 is formed on the buffer layer 16. The concentration of carbon C included in the first GaN layer 18 is higher than the concentration of C included in the second GaN layer 20. The concentration of C included in the second GaN layer 20 is, for example, 1.0×10¹⁷ atoms/cm³ or lower. The concentrations of C included in the first GaN layer 18 and the second GaN layer 20 may be measured by, for example, SIMS (Secondary Ion Mass Spectrometry) analysis.

An AlGaN electron supply layer 24 is formed directly on the upper surface of the GaN layer 22. 2DEG (two-Dimensional Electron Gas) is generated at the interface between the GaN layer 22 and the AlGaN electron supply layer 24, so that a channel layer 26 can be formed. That is, the channel layer 26 is formed in the second GaN layer 20. A GaN cap layer 28 is formed on the AlGaN electron supply layer 24. A source electrode 30 and a drain electrode 32, which are ohmic electrodes, are formed on the GaN cap layer 28. A gate electrode 34 is formed on the GaN cap layer 28 and is interposed between the source electrode 30 and the drain electrode 32.

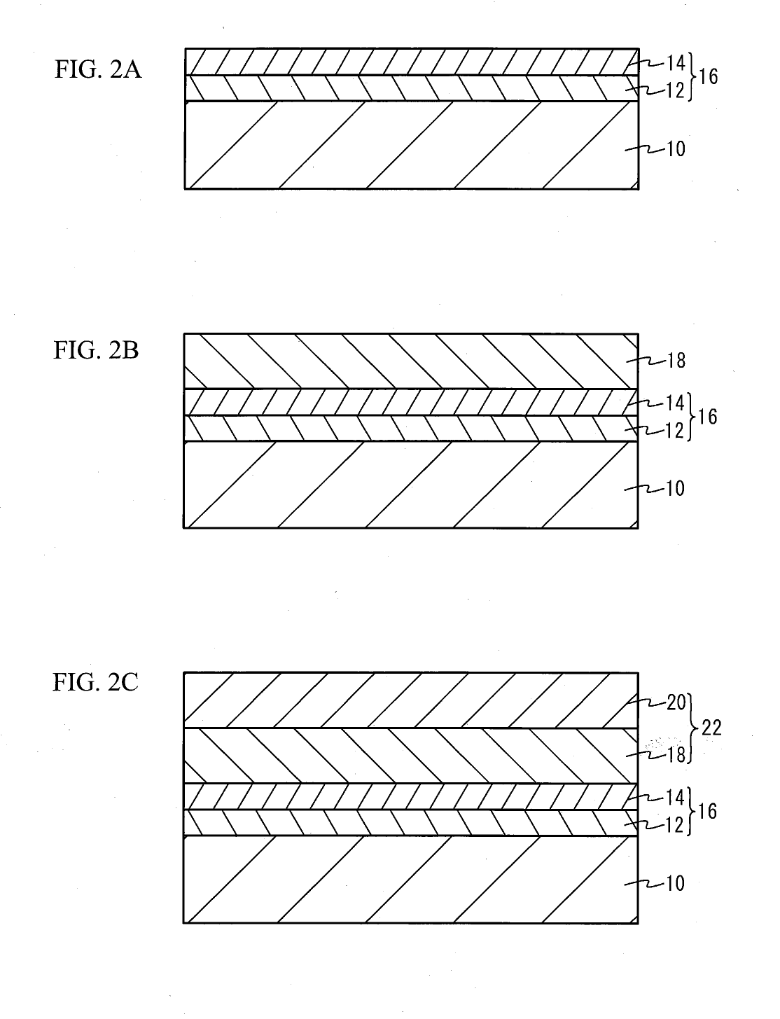

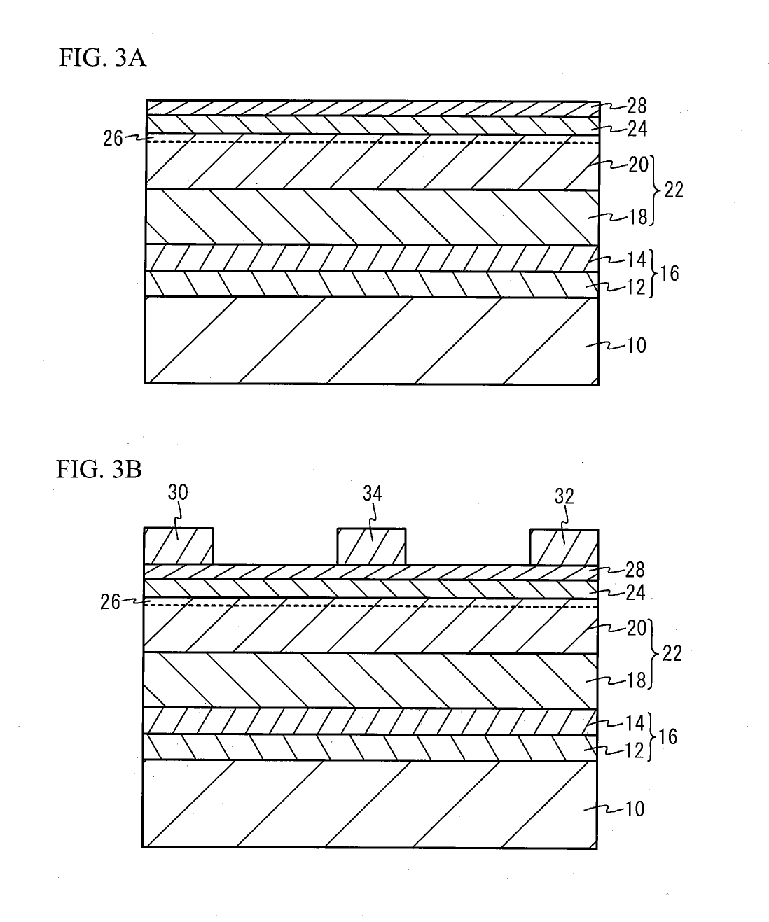

FIGS. 2A through 2C and FIGS. 3A and 3B are schematic cross-sectional views that illustrate a method for fabricating the semiconductor device in accordance with the first embodiment. Referring to FIG. 2A, the silicon substrate 10 is placed in, for example, a MOCVD (Metal Organic Chemical Vapor Deposition) chamber, and the AlN layer 12 is grown on the silicon substrate 10 under the following condition.

Source gas: NH₃ (ammonia), TMA (trimethylaluminium)

Growth temperature: 1100° C.

Thickness: 300 nm

Next, the AlGaN layer 14 is grown on the AlN layer 12 under the following condition.

Source gas: NH₃, TMA, TMG (trimethylgallium)

Growth temperature: 1100° C.

Al composition ratio: 50%

Thickness: 100 nm

Referring to FIG. 2B, the first GaN layer 18 is formed on the buffer layer 16 composed of the AlN layer 12 and the AlGaN layer 14 under the following condition.

Source gas: NH₃, TMG

Growth temperature: 1050° C.

Growth pressure: 100 torr

Growth rate: 1.0 μm/hour

V/III ratio: 2000

Thickness: 300 nm

Referring to FIG. 2C, the second GaN layer 20 is formed on the first GaN layer 18 under the following condition.

Source gas: NH₃, TMG

Growth temperature: 1050° C.

Growth pressure: 100 torr

Growth rate: 1.0 μm/hour

V/III ratio: 10000

Thickness: 700 nm

The V/III ratio of the first GaN layer 18 and the V/III ratio of the second GaN layer 20 are changed by changing the flow rate of NH3 gas. The NH₃ partial pressure at the time of growing the first GaN layer 18 is set lower than the NH₃ partial pressure at the time of growing the second GaN layer 20.

Referring to FIG. 3A, the AlGaN electron supply layer 24 is grown on the second GaN layer 20 under the following condition.

Source gas: NH₃, TMA, TMG

Al composition ratio: 20%

Thickness: 20 nm

Then, the GaN cap layer 28 is grown on the AlGaN electron supply layer 24 under the following condition.

Source gas: NH₃, TMG

Thickness 2 nm

Referring to FIG. 3B, the source electrode 30 and the drain electrode 32 are formed on the GaN cap layer 28 by sequentially stacking Ti (titanium) and Al (aluminum) in this order by using, for example, an evaporating deposition method and a lift-off method. Then, annealing is carried out at 500° C.˜800 ° C., for example, to form the ohmic electrodes of the source electrode 30 and the drain electrode 32. Then, the gate electrode 34 is formed on the GaN cap layer 28 and is located between the source electrode 30 and the drain electrode 32 by sequentially stacking Ni (nickel) and Au (gold) in this order by using, for example, the evaporating deposition method and the lift-ff method. The semiconductor device of the first embodiment is produced as described above.

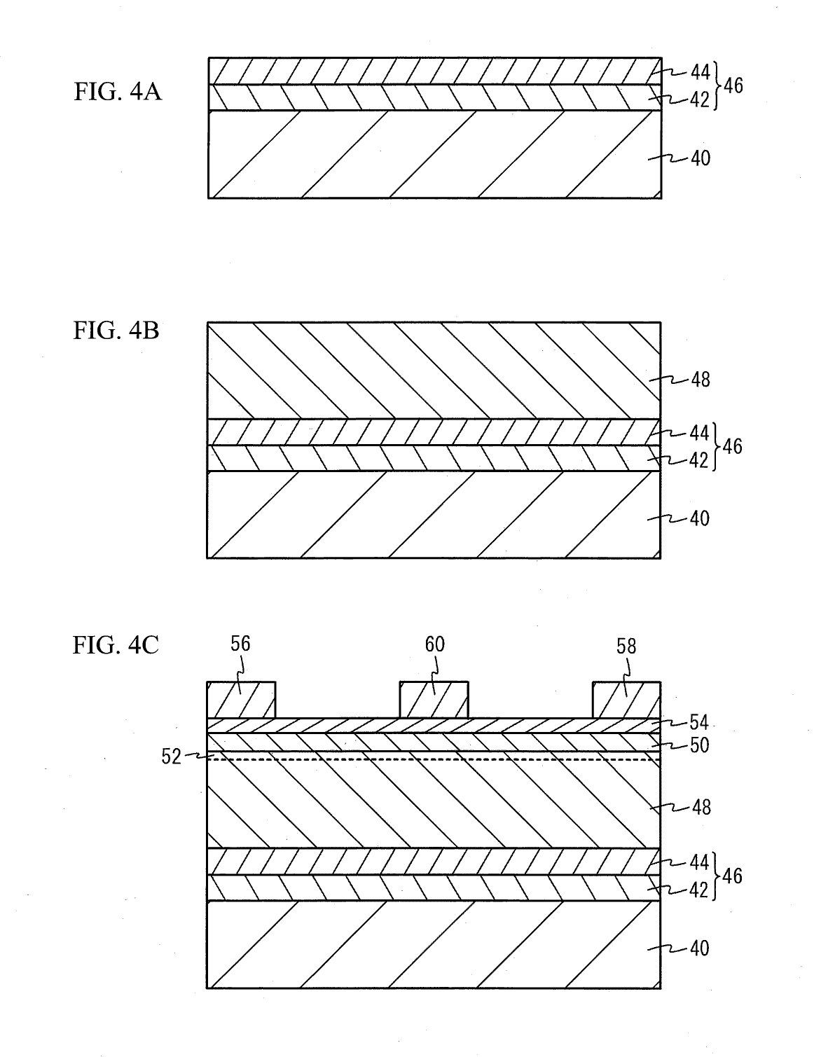

A method for fabricating a semiconductor device in accordance with a first comparative example is now described. FIGS. 4A through 4C are schematic cross-sectional views that illustrate a method for fabricating a semiconductor device in accordance with the first comparative example. Referring to FIG. 4A, a silicon substrate 40 is placed in the MOCVD chamber, and an AlN film 42 is formed on the silicon substrate 40 under the following condition.

Source gas: NH₃, TMA

Growth temperature: 1100° C.

Thickness: 300 nm

Next, an AlGaN layer 44 is formed on the AlN layer 42 under the following condition.

Source gas: NH₃, TMA, TMG

Growth temperature: 1100° C.

Al composition ratio: 50%

Thickness: 100 nm

Referring to FIG. 4B, a GaN layer 48 is formed on a buffer layer 46 composed of the AlN layer 42 and the AlGaN layer 44.

Source gas: NH₃, TMG

Growth temperature: 1050° C.

Growth pressure: 100 torr

Growth rate: 1.0 μm/hour

V/III ratio: 10000

Thickness: 1000 nm

Referring to FIG. 4C, an AlGaN electron supply layer 50 is grown on the GaN layer 48 under the following condition.

Source gas: NH₃, TMA, TMG

Al composition ratio: 20%

Thickness: 20 nm

Then, a GaN cap layer 54 is formed on the AlGaN electron supply layer 50 under the following condition.

Source gas: NH₃, TMG

Thickness 2 nm

Finally, the source electrode 56, the drain electrode 58 and the gate electrode 60 are formed on the GaN cap layer 54 by the evaporating deposition method and the lift-off method. The semiconductor device of the first comparative example is fabricated as described above.

The inventors investigated the crystal quality of the GaN layer 22 of the first embodiment and investigated the quality of the GaN layer 48 of the first comparative example. In the investigation of the crystal quality, the inventors prepared a sample configured to form up to the GaN layer 22 illustrated in FIG. 2C, and another sample configured to form up to the GaN layer 48 illustrated in FIG. 4B, and checked an FWHM (Full Width at Half Maximum) of a rocking curve of a (002) plane of the GaN layer in each sample and that of a (102) plane thereof by x-ray diffraction. In the GaN layer 48 of the first comparative example, the FWHM of the (002) plane was 500 sec, and the FWHM of the (102) plane was 900 sec. In contrast, in the GaN layer 22 of the first embodiment, the FWHM of the (002) plane was 500 sec, and the FWHM of the (102) plane was 650 sec. Thus, the FWHM of the (102) plane of the GaN 22 of the first embodiment is less than that of the GaN layer 48 of the first comparative example. This means that the crystal quality of the first embodiment is improved. That is, the dislocation density is reduced.

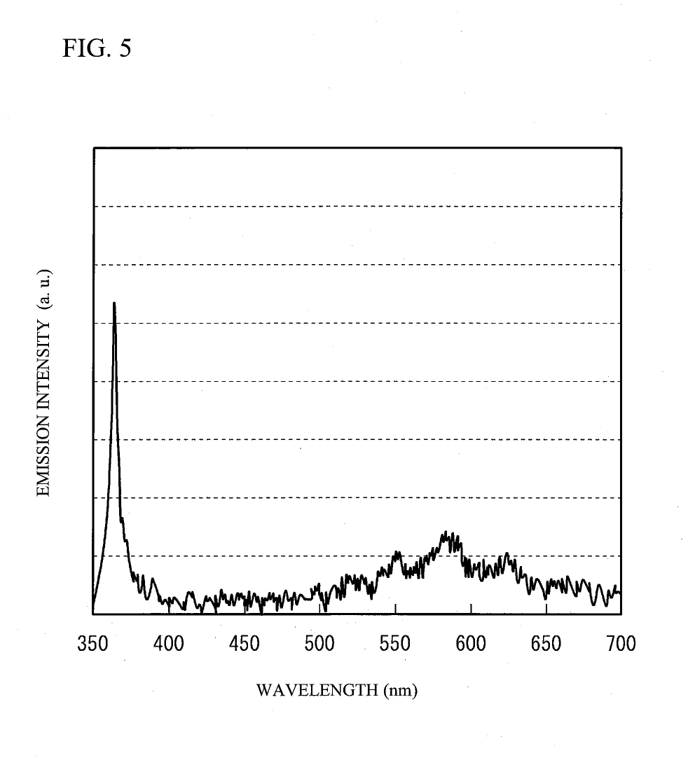

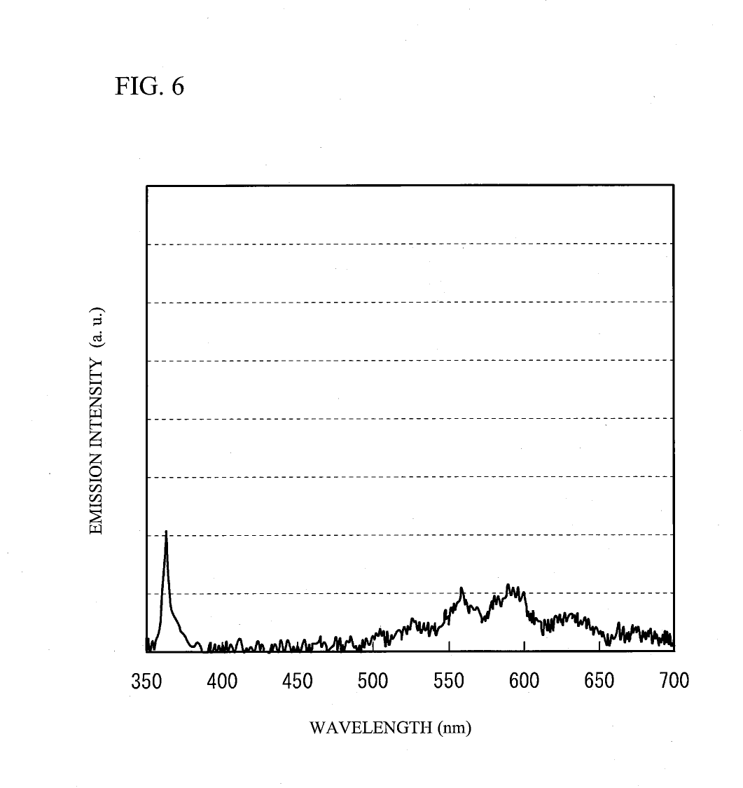

The photoluminescence of the GaN layer 22 of the first embodiment and the GaN 48 of the first comparative example was evaluated by measuring the photoluminescence of the sample configured to form up to the GaN layer 22 illustrated in FIG. 2C and the sample confirmed to form up to the GaN layer 48 illustrated in FIG. 4B. FIG. 5 illustrates the result of measurement of the emission spectrum of the GaN layer 22 of the first embodiment. FIG. 6 illustrates the result of measurement of the emission spectrum of the GaN layer 48 of the first comparative example. In FIGS. 5 and 6, the horizontal axis denotes wavelength, and the vertical axis denotes the emission intensity.

As illustrated in FIGS. 5 and 6, the band-edge emission strength of the GaN layer 48 of the first comparative example was approximately 10 (a. u.), while the band-edge emission strength of the GaN layer 22 of the first embodiment was approximately 25 (a. u.). That is, the first embodiment had an band-edge emission intensity equal to approximately 2.5 times that of the first comparative example. The band-edge emission intensity is the intensity of light emission at about 360 nm. It can also be seen from the above that the GaN layer 22 of the first embodiment has a reduced displacement density and an improved crystal quality.

The reason why the crystal quality of the GaN layer 22 of the first embodiment has an improved crystal quality as compared with the GaN layer 48 of the first comparative example may be considered as follows. GaN is grown to form the GaN layer 48 of the first comparative example at a V/III ratio as high as 10000. When GaN is grown at such a high V/III ratio, the crystal quality of the GaN epitaxial layer itself is degraded. Thus, the FWHM increases and the band-edge emission intensity becomes lower. In contrast, the GaN layer 22 of the first embodiment is formed by growing the first GaN layer 18 at a V/III ratio as low as 2000 and then growing the second GaN layer 20 at a high V/III ratio. Thus, the GaN layer 22 of the first embodiment has an improved crystal quality, a small FWHM and a large band-edge emission intensity, as compared with the first GaN layer 48 of the first comparative example.

As illustrated in FIGS. 5 and 6, the intensity of broad emission in a band of 500˜700 nm (yellow band: YB intensity) was approximately 5 (a. u.) in the first embodiment and the first comparative example. The YB intensity depends on the number of traps in GaN. Thus, a larger YB intensity means more traps in GaN, which is a cause of current collapse. The GaN layer 22 of the first embodiment has traps as small as those of the GaN layer 48 of the first comparative example.

It is now supposed that the second GaN layer 20 is not provided on the first GaN layer 18 but the GaN layer 22 is formed by only the first GaN layer 18. In this case, the crystal quality of the GaN layer 22 is improved. Thus, the FWHM is comparatively small and the band-edge emission intensity is comparatively large. However, since the first GaN layer 18 is grown at a low V/III ratio, more carbon (C) atoms are taken in the first GaN layer 18, and the C concentration increases. The C atoms act as traps. Thus, in the case where the GaN layer 22 is formed by only the first GaN layer 18, the YB intensity of the GaN layer 22 increases. Further, the first GaN layer 18 grown at a low V/III ratio tends to have cracks or pits on the surface thereof. Thus, cracks and pits are formed on the upper surface of the GaN layer 22. This is not good because the AlGaN electron supply layer 24 is formed on the GaN layer 22.

Taking the above into consideration, according to the first embodiment, the second GaN layer 20 is formed on the first GaN layer 18 at a high V/III ratio, which is, for example, 10000. Since the second GaN layer 20 is formed at a high V/III ratio, the C concentration is low. Thus, it is possible to suppress the C concentration of the whole GaN layer 22 to a low level and realize an YB intensity almost equal to that of the GaN layer 48 of the first comparative example. Since the second GaN layer 20 is formed at a high V/III ratio, cracks or pits hardly occur on the surface thereof. It is thus possible to suppress the occurrence of cracks or pits on the upper surface of the GaN layer 22.

As described above, according to the first embodiment, when the first GaN layer 18 is formed on the buffer layer 16 on the silicon substrate 10 and the second GaN layer 20 is formed directly on the first GaN layer 18, the V/III ratio of the first GaN layer 18 is set lower than the V/III ratio of the second GaN layer 20. As GaN is grown at a lower V/III ratio, a larger number of C atoms is taken in the GaN layer and the C concentration is higher. Thus, the concentration of C included in the first GaN layer 18 is higher than that of C included in the second GaN layer 20. Thus, as has been described, the GaN layer 22 composed of the first GaN layer 18 and the second GaN layer 20 has a small FWHM and a large band-edge emission intensity, so that the crystal quality can be improved. By stacking the second GaN layer 20 on the upper surface of the first GaN layer 18 in which the C concentration of the second GaN layer 20 is lower than that of the first GaN layer 18, it is possible to suppress the C concentration of the whole GaN layer 22 to a low level and suppress increase in the YB intensity. Thus, the GaN layer 22 having a smaller number of traps can be realized. Further, cracks or pits are hardly formed on the surface of the second GaN layer 20 that is grown at a high V/III ratio. It is thus possible to suppress the occurrence of cracks or pits on the upper surface of the GaN layer 22. According to the first embodiment, the GaN layer 22 formed on the silicon substrate 10 so as to interpose the buffer layer 16 therebetween has an improved crystal quality.

In the first embodiment, in order to set the V/III ratio at the time of growing the first GaN layer 18 lower than the V/III ratio at the time of growing the second GaN layer 20, the partial pressure of NH3 gas for growing the first GaN layer 18 is set lower than that for growing the second GaN layer 20. Another method for adjusting the V/III ratio may be used. For example, the V/III ratio may be adjusted by changing the quantity of the MO source. In this case, the quantity of the MO source for growing the first GaN layer 18 may be set larger than the quantity of the MO source for growing the second GaN layer 20.

The concentration of C included in the second GaN layer 20 is preferably equal to or lower than 1.0×1017 atoms/cm3, and is more preferably equal to or lower than 7.0×1016 atoms/cm3, and is much more preferably equal to or lower than 5.0×1016 atoms/cm3. It is thus possible to suppress the occurrence of cracks or pits on the upper surface of the GaN layer 22 and suppress increase in the YB intensity.

The thickness of the first GaN layer 18 is not limited to 300 nm. However, if the first GaN layer 18 is too thick, the cracks or pits formed on the surface of the first GaN layer 18 are not buried and cracks or pits occur on the surface of the second GaN layer 20 even when the second GaN layer 20 is formed on the first GaN layer 18. That is, cracks or pits are formed on the upper surface of the GaN layer 22. Thus, the thickness of the first GaN layer 18 is preferably equal to or smaller than 500 nm, and is more preferably equal to or smaller than 300 nm, and is much more preferably equal to or smaller than 200 nm. The thickness of the GaN layer 22 composed of the first GaN layer 18 and the second GaN layer 20 is not limited to 1000 nm but is preferably 800 nm˜1500 nm, and is more preferably 1000 nm 1300 nm.

The buffer layer 16 interposed between the silicon substrate 10 and the first GaN layer 18 is not limited to the combination of the AlN layer 12 on the silicon substrate 10 and the AlGaN layer 14 on the AlN layer 12 but may be made of another material having a band gap greater than that of GaN. The electron supply layer is not limited to AlGaN but may be made of another material having a band gap greater than that of GaN.

In the above description, the first embodiment changes the V/III ratio once so that the GaN layer 22 composed of the first GaN layer 18 and the second GaN layer 20 can be formed. However, the first embodiment is not limited to the above. For example, the V/III ratio may be changed twice or more to form the GaN layer 22 composed of three or more layers. The C concentrations of the layers stacked to form the GaN layer 22 become low from the lowermost layer to the uppermost layer. It is also possible to gradually increase the V/III ratio so that the C concentration gradually decreases from the side close to the buffer layer 16 to the other side close to the AlGaN electron supply layer 24.

The present invention is not limited to the specifically described embodiments but various embodiments and variations may be made without departing from the scope of the present invention.

What is claimed is:

1. A semiconductor device comprising:
a silicon substrate;
a buffer layer provided on the silicon substrate and has a band gap greater than GaN;
a first GaN layer provided on the buffer layer; and
a second GaN layer provided directly on the first GaN layer,
a carbon concentration of the first GaN layer being higher than a carbon concentration of the second GaN layer.

2. The semiconductor device according to claim 1, further comprising an electron supply layer that is provided on the second GaN layer and has a band gap greater than GaN.

3. The semiconductor device according to claim 1, wherein the buffer layer includes an AlN layer provided on the silicon substrate and an AlGaN layer provided on the AlN layer.

4. The semiconductor device according to claim 1, wherein the carbon concentration of the second GaN layer is 1.0×10¹⁷ atoms/cm³ or lower.

5. The semiconductor device according to claim 1, wherein the carbon concentration of the second GaN layer is 7.0×10¹⁶ atoms/cm³ or lower.

6. The semiconductor device according to claim 1, wherein the carbon concentration of the second GaN layer is 5.0×10¹⁶ atoms/cm³ or lower.

7. The semiconductor device according to claim 1, wherein the first GaN layer has a thickness of 500 nm or less.

8. The semiconductor device according to claim 1, wherein the first GaN layer has a thickness of 300 nm or less.

9. The semiconductor device according to claim 1, wherein the first GaN layer has a thickness of 200 nm or less.

10. The semiconductor device according to claim 7, wherein a total thickness of the first GaN layer and the second GaN layer is between 800 nm and 1500 nm.

11. The semiconductor device according to claim 7, wherein a total thickness of the first GaN layer and the second GaN layer is between 1000 nm and 1300 nm.

12. A method for fabricating a semiconductor device comprising:
forming a buffer layer on a silicon substrate, the buffer layer having a band gap greater than GaN;
forming a first GaN layer on the buffer layer by MOCVD; and
forming a second GaN layer directly on the first GaN layer by MOCVD,
a V/III ratio of the MOCVD in the forming of the first GaN layer being lower than a V/III ratio of the MOCVD in the forming of the second GaN layer.

13. The method according to claim 12, wherein a NH₃ partial pressure of the MOCVD in the forming of the first GaN layer is lower than NH₃ partial pressure of the MOCVD in the forming of the second GaN layer.

14. The method according to claim 12, wherein the formation of the second GaN layer is carried out by growing the second GaN layer continuously from the first GaN layer and changing the V/III ratio of the MOCVD from the first GaN layer.
